(19) United States
(12) Patent Application Publication
(10) Pub. No.: US 2023/0307430 A1
(43) Pub. Date: Sep. 28, 2023

(54) SEMICONDUCTOR DEVICE

(71) Applicants: KABUSHIKI KAISHA TOSHIBA, Tokyo (JP); TOSHIBA ELECTRONIC DEVICES & STORAGE CORPORATION, Tokyo (JP)

(72) Inventors: Yuning TSAI, Yokohama Kanagawa (JP); Yoshiko Takahashi, Yokohama Kanagawa (JP)

(73) Assignees: KABUSHIKI KAISHA TOSHIBA, Tokyo (JP); TOSHIBA ELECTRONIC DEVICES & STORAGE CORPORATION, Tokyo (JP)

(21) Appl. No.: 17/942,510

(22) Filed: Sep. 12, 2022

(30) Foreign Application Priority Data
Mar. 22, 2022 (JP) 2022-045005

(51) Int. Cl. H01L 25/16; H01L 23/00

(52) U.S. Cl. CPC H01L 25/167; H01L 24/37; H01L 24/40; H01L 24/48; H01L 24/49; H01L 24/73; H01L 24/32; H01L 2224/32245; H01L 2224/37147; H01L 2224/40139; H01L 2224/40175; H01L 2224/48106; H01L 2224/48175; H01L 2224/49111; H01L 2224/73221; H01L 2224/73263; H01L 2224/73265

(57) ABSTRACT

According to one embodiment, a semiconductor device includes a package substrate including a package member and a first conductive portion; a semiconductor package provided on a first surface of the package substrate inside the package member and coupled to the first conductive portion; a first semiconductor chip provided on the first surface of the package substrate inside the package member and including a first terminal; a second semiconductor chip provided on the first surface of the package substrate inside the package member and including a second terminal; and a connection component that couples the first and second terminals to the first conductive portion inside the package member.

### CROSS-REFERENCE TO RELATED APPLICATIONS

This application is based upon and claims the benefit of priority from Japanese Patent Application No. 2022-045005, filed Mar. 22, 2022, the entire contents of which are incorporated herein by reference.

### FIELD

Embodiments described herein relate generally to a semiconductor device.

### BACKGROUND

Semiconductor devices with various package structures have been proposed in an effort to reduce size and improve device functionality.

### BRIEF DESCRIPTION OF THE DRAWINGS

FIG. 1 is a schematic view showing an apparatus including a semiconductor device of an embodiment.

FIG. 2 is a bird’s-eye view showing a structural example of a semiconductor device of a first embodiment.

FIG. 3 is a plan view showing a structural example of the semiconductor device of the first embodiment.

FIG. 4 is a plan view showing a structural example of the semiconductor device of the first embodiment.

FIG. 5 is a cross-sectional view showing a structural example of the semiconductor device of the first embodiment.

FIG. 6 is a circuit diagram showing a circuit configuration of the semiconductor device of the first embodiment.

FIG. 7 is a bird’s-eye view showing a structural example of a semiconductor device of a second embodiment.

FIG. 8 is a cross-sectional view showing a structural example of the semiconductor device of the second embodiment.

FIG. 9 is a bird’s-eye view showing a modification of the semiconductor device of the embodiment.

FIG. 10 is a cross-sectional view showing the modification of the semiconductor device of the embodiment.

### DETAILED DESCRIPTION

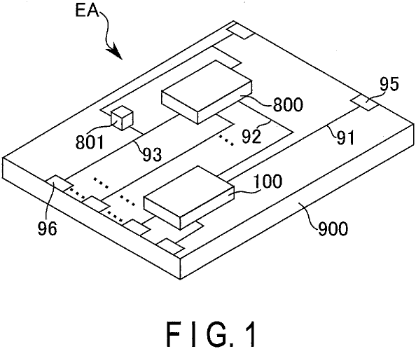

A semiconductor device of an embodiment will be described in detail with reference to FIGS. 1 to 10. In the description below, elements having the same functions and configurations will be denoted by the same reference symbols.

In the embodiments described below, where constituent elements denoted by reference symbols to which numbers/letters are attached at the end for discrimination (e.g., circuits, interconnects, various voltages and signals) do not have to be discriminated from each other, reference symbols without the numbers/letters at the end will be used.

In general, according to one embodiment, a semiconductor device includes a package substrate including a package member and a first conductive portion; a semiconductor package provided on a first surface of the package substrate inside the package member and coupled to the first conductive portion; a first semiconductor chip provided on the first surface of the package substrate inside the package member and including a first terminal; a second semiconductor chip provided on the first surface of the package substrate inside the package member and including a second terminal; and a connection component that couples the first and second terminals to the first conductive portion inside the package member.

### Embodiments

### First Embodiment

A semiconductor device of the first embodiment will be described with reference to FIGS. 1 to 6.

### Structural Example

FIG. 1 is a schematic view for illustrating an apparatus incorporating the semiconductor device 100 of the present embodiment.

As shown in FIG. 1, the semiconductor device 100 of the present embodiment is provided in a certain electric device EA. For example, the electric device EA is an industrial machine, a power conversion apparatus, an in-vehicle device, a home appliance device, an acoustic device, a video device, a communication device, a computing system, or the like.

The semiconductor device 100 is arranged on a module board (also referred to as a motherboard or a printed wiring board) 900 together with one or more other devices (e.g., other semiconductor devices or electronic components) 800, 801.

The module board 900 includes a plurality of interconnects 91, 92, 93 and a plurality of terminals 95, 96.

The plurality of interconnects 91, 92, 93 are provided on the surface of the module board 900 or inside the module board 900. Each of the interconnects 91, 92, 93 is coupled to one or more of the corresponding terminals (connectors, sockets or slots) 95, 96, or to devices 100, 800, 801 on the module board 900. Each of the terminals 95, 96 is supplied with one of voltages (e.g., power supply voltage or ground voltage) or one of signals.

The semiconductor device 100 is coupled to a plurality of interconnects 91, 92 of the module board 900. For example, on the module board 900, the semiconductor device 100 is coupled to the terminal 95 via the interconnect 91 or to the semiconductor device 800 (or the electronic component 801) via the interconnect 92.

The semiconductor device 800 includes, for example, a semiconductor integrated circuit or a discrete device. The semiconductor device 800 may be a module device including a plurality of chips and a plurality of passive elements. The electronic component 801 is a passive element such as a capacitor, an inductor, a resistor or a switch.

The semiconductor device 800 and the electronic component 801 are coupled to the terminal 96 via the interconnect 93, or are coupled to each other via another interconnect.

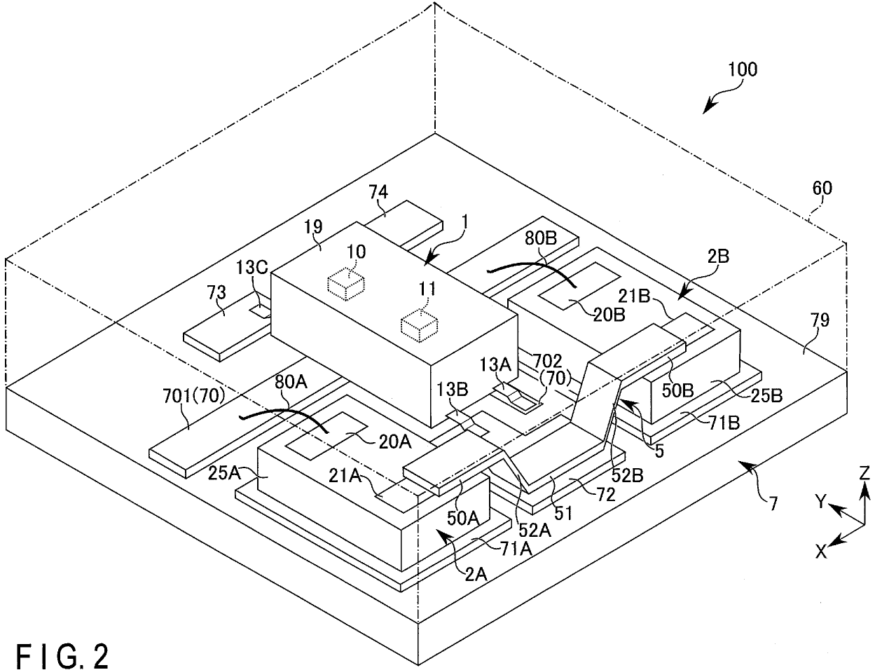

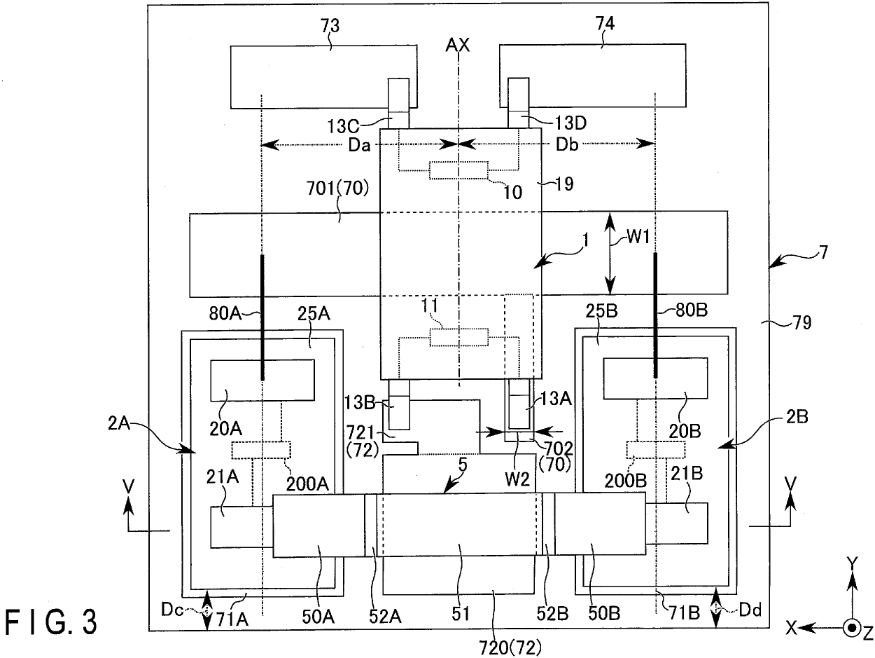

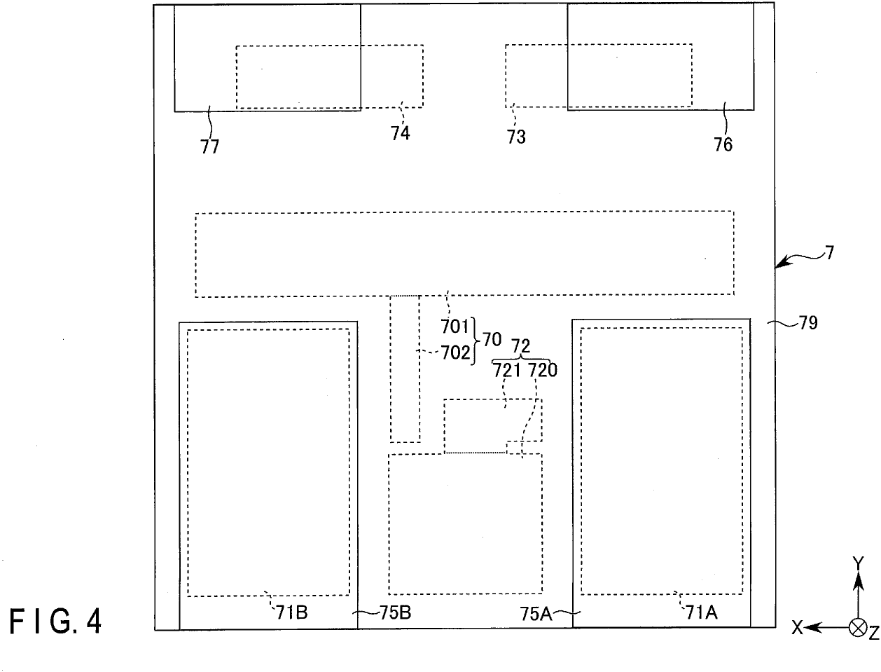

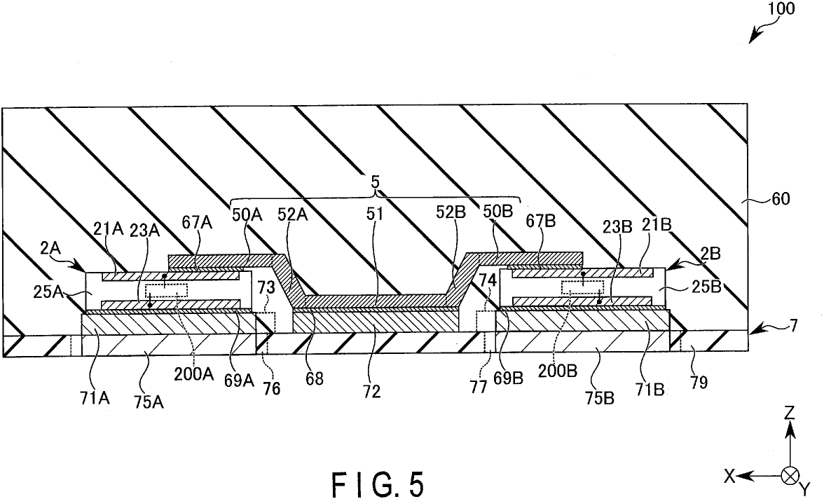

FIG. 2 is a schematic bird’s-eye view for illustrating the structure of the semiconductor device 100 of the present embodiment. FIG. 3 is a plan view schematically showing the structure of the front surface side (one major surface side) of the semiconductor device 100 of the present embodiment. FIG. 4 is a plan view schematically showing the structure of the back surface side (the other major surface side) of the semiconductor device 100 of the present embodiment. FIG. 5 is a cross-sectional view schematically showing a cross-sectional structure of the semiconductor device 100 of the present embodiment. In FIG. 5, a cross section taken along line V-V of FIG. 3 is shown.

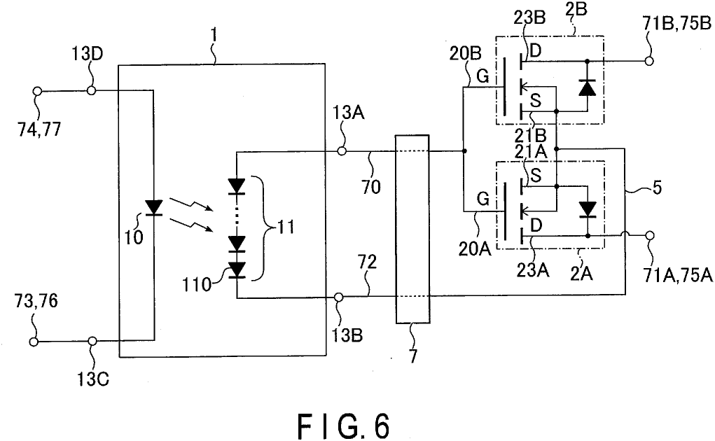

FIG. 6 is a circuit diagram for illustrating a circuit configuration of the semiconductor device 100 of the present embodiment.

As shown in FIGS. 2 to 5, the semiconductor device 100 of the present embodiment includes one semiconductor package (also referred to as a package device) 1 and two semiconductor chips 2 (2A, 2B). The semiconductor device 100 of the present embodiment is a surface mount device (SMD).

The one semiconductor package 1 and the semiconductor chips 2A, 2B are provided on the package substrate 7. The semiconductor package 1 and the semiconductor chips 2A, 2B are covered with a package member (also referred to as an insulating resin, a sealing resin, or a mold resin) 60 on the package substrate 7. In FIG. 2, the package member 60 is shown as a dashed-dotted frame for ensuring visibility.

The semiconductor device 100 of the present embodiment has a package-in-package (PiP) structure with respect to the semiconductor package 1.

The package substrate 7 includes a substrate member 79, a lead frame 70, a plurality of die pads 71A, 71B, a plurality of electrodes 72, 73, 74, and a plurality of terminals 75A, 75B, 76, 77.

The substrate member 79 is an insulator. For example, the substrate member 79 is an insulating organic material (e.g., polyimide) or an insulating ceramic material. In the package substrate 7, the substrate member 79 supports the lead frame 70, the die pads 71A, 71B, the electrodes 72, 73, 74, and the terminals 75A, 75B, 76, 77.

The lead frame 70, the die pads 71A, 71B, the electrodes 72, 73, 74, and the terminals 75A, 75B, 76, 77 are separate from each other.

The lead frame 70, the die pads 71A, 71B, the electrodes 72, 73, 74, and the terminals 75A, 75B, 76, 77 include (contain) copper (Cu).

The lead frame 70 is arranged in the region between the region where the electrodes 73, 74 are provided and the region where the electrodes 72 are provided.

The upper surface of the lead frame 70 is exposed from the substrate member 79.

The lead frame 70 includes a first lead portion 701 and a second lead portion 702. The two lead portions 701, 702 are constituted by one continuous conductor.

The first lead portion 701 has a quadrangular shape (line shape) extending in the X direction as viewed in the Z direction. The second lead portion 702 has a quadrangular shape (line shape) extending in the Y direction, as viewed in the Z direction. The lead frame 70 has a T-shape (or a shape similar to the T-shape) as viewed in the Z direction. The X direction is a direction parallel to the surface of the package substrate 7. For example, the X direction is parallel to the direction in which the two semiconductor chips 2A, 2B are arranged side by side. The Y direction is a direction parallel to the surface of the package substrate 7 and intersecting the X direction (e.g., orthogonal thereto). The Z direction is a direction perpendicular to the surface of the package substrate 7.

The first lead portion 701 extends from one end side of the package substrate 7 toward the other end side, in the X direction. One end of the first lead portion 701 in the X direction is located near one end of the package substrate 7 in the X direction. The other end of the first lead portion 701 in the X direction is located near the other end portion of the package substrate 7 in the X direction. The first lead portion 701 passes through the lower region of the semiconductor package 1 in the Z direction. The first lead portion 701 partially overlaps the semiconductor package 1 as viewed in the Z direction. For example, the first lead portion 701 is not in direct contact with the semiconductor package 1.

One end of the second lead portion 702 is coupled to the first lead portion 701. The second lead portion 702 passes through the lower region of the semiconductor package 1 in the Z direction and extends from the first lead portion 701 toward the connection terminal 13A side of the semiconductor package 1. The second lead portion 702 extends in the Y direction.

It should be noted that the lead frame 70 may also be referred to as a lead portion, a pad, a conductive portion, an interconnect or a connection member.

The upper surfaces of the two die pads 71 (71A, 71B) are exposed from the substrate member 79. The die pad 71A is separate from the die pad 71B. The die pad 71 functions as a mounting portion for the semiconductor chip 2 and also functions as a connection member (electrode, pad) of the semiconductor chip 2. For example, the die pad 71 (71A, 71B) is also referred to as a base portion, a mount portion, or a stage.

The two die pads 71A, 71B are arranged in the X direction, with the electrode 72 interposed therebetween. The die pads 71A, 71B are adjacent to the lead portion 701 in the Y direction.

For example, the two die pads 71A, 71B are arranged inside the package substrate 7 symmetrically, with a line along the Y direction and passing through the center of the package substrate 7 as an axis of symmetry.

The electrode 72 is provided on one end side of the package substrate 7 in the Y direction. The electrode 72 is arranged side by side with the semiconductor package 1 in the Y direction, as viewed in the Z direction. The electrode 72 is provided in the region between the die pads 71A, 71B in the X direction. The upper surface of the electrode 72 is exposed from the substrate member 79.

The electrode 72 includes two portions (also referred to as electrode portions) 720, 721. The portion 720 has a quadrangular planar shape as viewed in the Z direction. The portion 721 has a hook-like planar shape as viewed in the Z direction. The portion 720 and the portion 721 are constituted by one continuous conductor.

The portion 720 is provided between the two die pads 71 in the X direction.

The portion 721 is adjacent to the lead portion 702 in the X direction. It should be noted that the portion 721 (and the portion 720) is separate from the lead portion 702.

The electrodes 73, 74 are provided on the other end side of the package substrate 7 in the Y direction. The electrodes 73, 74 are opposed to the electrode 72, with the lead frame 70 interposed therebetween.

The upper surfaces of the electrodes 73, 74 are exposed from the substrate member 79. The electrodes 73, 74 have a quadrangular planar shape as viewed in the Z direction.

The electrode 73 is separate from the electrode 74.

Each of the electrodes 72, 73, 74 is also referred to as a lead portion, a pad, a conductive portion or a connection member.

The space between the lead frame 70, the die pad 71 and the electrodes 72, 73, 74 in the direction parallel to the surface of the package substrate 7 may be embedded with the package member 60 or the substrate member 79.

In the present embodiment, the terminals (hereinafter referred to as external connection terminals) 75 (75A, 75B), 76, 77 are provided on the back surface side of the package substrate 7. The external connection terminals 75, 76, 77 are terminals for coupling the semiconductor device 100 to another device (or an interconnect on the module board or a terminal of the module board). For example, the external connection terminals 75, 76, 77 are provided in the opening formed in the substrate member 79.

The external connection terminal 75A is provided at a position overlapping the die pad 71A in the Z direction. The external connection terminal 75B is provided at a position overlapping the die pad 71B in the Z direction.

The external connection terminals 75 have a quadrangular planar shape as viewed in the Z direction.

The external connection terminals 75 are exposed from the substrate member 79 on the back surface side of the package substrate 7. The side surfaces of the external connection terminals 75 may be exposed from the side surfaces of the package substrate 7, so that the external connection terminals 75 have a WF (Wettable Flank) structure.

In the example shown in FIG. 5, the external connection terminals 75 are coupled directly to (or in direct contact with) the die pads 71. It should be noted the external connection terminals 75 may be electrically coupled to the die pads 71 on the front surface side of the package substrate 7 via a contact portion provided in the substrate member 79. Each external connection terminal 75 may be one conductor continuous with the die pad 71.

The external connection terminal 76 is provided on the back surface side of the package substrate 7 such that it partially overlaps the electrode 73 in the Z direction.

Substantially similar to the structure of the die pad 71 and the external connection terminals 75 in the example shown in FIG. 5, the external connection terminal 76 is coupled directly to (or in direct contact with) the electrode 73. It should be noted, however, the external connection terminal 76 may be electrically coupled to the electrode 73 on the front surface side of the package substrate 7 via a contact portion (not shown) provided in the substrate member 79. The external connection terminal 76 may be one conductor continuous with the electrode 73.

The external connection terminal 77 is provided on the back surface side of the package substrate 7 such that it partially overlaps the electrode 74 in the Z direction.

Substantially similar to the structure of the die pad 71 and the external connection terminals 75 in the example shown in FIG. 5, the external connection terminal 77 is coupled directly to (or in direct contact with) the electrode 74. It should be noted, however, the external connection terminal 77 may be electrically coupled to the electrode 74 on the front surface side of the package substrate 7 via a contact portion (not shown) provided in the substrate member 79. The external connection terminal 77 may be one conductor continuous with the electrode 74.

The external connection terminals 76, 77 have a quadrangular planar shape as viewed in the Z direction.

The external connection terminals 76, 77 are exposed from the substrate member 79 on the back surface side of the package substrate 7. The side surfaces of the external connection terminals 76, 77 may be exposed from the side surfaces of the package substrate 7 so that the external connection terminals 76, 77 have a WF structure.

The lead frame 70, die pad 71, and electrodes 72, 73, 74 which are provided on the front surface side of the package substrate 7 may be referred to as front surface electrodes (or front surface pads), and the external connection terminals 75, 76 which are provided on the back surface side of the package substrate 7 may be referred to as back surface electrodes (or back surface pads).

The semiconductor package 1 is provided on the front surface of the package substrate 7. The semiconductor package 1 is arranged above the lead frame 70 in the Z direction. The semiconductor package 1 is arranged in the region between the two semiconductor chips 2A, 2B that are adjacent to each other in the X direction. A portion of the semiconductor package 1 is sandwiched between the two semiconductor chips 2A, 2B in the X direction. For example, the semiconductor package 1 is arranged in the central region of the package substrate 7.

Inside the package member 19, the semiconductor package 1 includes a first circuit unit 10 and a second circuit unit 11. For example, the package member 19 is an insulator including a light-shielding layer (light-shielding member). For example, the material of the package member 19 is different from the material of the package member 60.

The semiconductor package 1 has four connection terminals (also referred to as connection nodes or lead units) 13A, 13B, 13C and 13D coupled to the circuit units 10, 11. The connection terminals 13A, 13B are provided on one end side of the semiconductor package 1 as viewed in the Y direction. The connection terminals 13C, 13D are provided on the other end side of the semiconductor package 1 as viewed in the Y direction.

The connection terminal 13A is coupled to the second lead portion 702 of the lead frame 70 via a conductive member (not shown), such as a conductive paste or solder.

The connection terminal 13B is coupled to the portion 721 of the electrode 72 via a conductive member.

The connection terminal 13C is coupled to the electrode 73 via a conductive member.

The connection terminal 13D is coupled to the electrode 74 via a conductive member.

The dimension W2 of the second lead portion 702 in the width direction thereof (X direction) is smaller than the dimension W1 of the first lead portion 701 in the width direction thereof (Y direction). Thus, the size of that portion 702 of the lead frame 70 which is coupled to the connection terminal 13A is reduced. With this structure, the present embodiment prevents the conductive member (solder or the conductive paste) from spreading eve if the conductive member is wet. As a result, short circuiting between the connecting portions (e.g., short circuiting between the connection terminal 13A and the electrode 72 or short circuiting between the connection terminal 13A and the die pad 71B) due to the spread of the conductive member is prevented. In addition, the distance between the connection portions can be reduced, and the area of the package substrate 7 can be reduced.

The portion 721 of the electrode 72 coupled to the connection terminal 13B has a hook-like shape. Thus, a slit is formed in the region between the portion 721 and the portion 720. With this structure, the spread of the conductive member due to the wet conductive member can be suppressed. As a result, short circuiting between the terminals due to the spread of the conductive member (e.g., short circuiting between the connection terminal 13B and the die pad 71B) is prevented.

On the front surface of the package substrate 7, the semiconductor chip 2A is provided on the die pad 71A. On the front surface of the package substrate 7, the semiconductor chip 2B is provided on the die pad 71B.

The two semiconductor chips 2A, 2B partially sandwich the semiconductor package 1 in the X direction. For example, the semiconductor chips 2A, 2B are arranged on the front surface of the package substrate 7 such that they have a symmetrical layout, with the line AX passing through the center of the semiconductor package 1 in the X-Y plane (i.e., the line passing through the center of the package substrate 7 in the X-Y plane) as the axis of symmetry. The line AX, the axis of symmetry, is along the Y direction.

For example, the semiconductor chip 2A is located in the region surrounded by the lead frame 70 and the electrodes 72, in an area between the line AX and one end of the package substrate 7 in the X direction. For example, the semiconductor chip 2B is located in the region surrounded by the lead frame 70 and the electrodes 72, in an area between the line AX and the other end of the package substrate 7 in the X direction.

For example, the semiconductor chips 2A, 2B are provided in the region between the lead portion 701 of the lead frame 70 and one end portion of the package substrate 7 in the Y direction (i.e., the end portion located on the side where the electrode 72 is provided).

In the semiconductor chips 2A, 2B having a symmetrical layout, the distance Da between the line AX and the line along the Y direction and passing through the center of the semiconductor chip 2A is substantially equal to the distance Db between the line AX and the line along the Y direction and passing through the center of the semiconductor chip 2B.

In the semiconductor chips 2A, 2B having a symmetrical layout, the distance Dc between the end of the semiconductor chip 2A and the end of the package substrate 7 in the Y direction is substantially equal to the distance Dd between the end of the semiconductor chip 2B and the end of the package substrate 7 in the Y direction.

The semiconductor chips 2A, 2B are bare chips (bare dies) of semiconductor elements. The semiconductor chips 2A, 2B are sealed on the package substrate 7 by the package member 60. The semiconductor chips 2A, 2B are in direct contact with the package member 60.

The size of each of the semiconductor chips 2A, 2B is smaller than the size of the semiconductor package 1. For example, the dimensions (thickness, height) of the semiconductor chips 2A, 2B in the Z direction are smaller than the dimensions of the semiconductor package 1 in the Z direction.

The semiconductor chip 2A has a chip member 25A including an element portion 200A and an interconnect layer (e.g., a multi-layered interconnect structure). The semiconductor chip 2A has a plurality of pads (also referred to as connection terminals, connection nodes or electrodes) 20A, 21A, 23A inside the chip member 25A. The pads 20A, 21A, 23A are coupled to the element portion 200A in the chip member 25A. An element is formed on the semiconductor substrate in the element portion 200A.

The pads 20A, 21A are provided on the upper surface side of the chip member 25A. The pad 23A is provided on the lower surface side of the chip member 25A. The lower surface of the chip member 25A is the surface on the side of the die pad 71A. The upper surface of the chip member 25A faces the lower surface of the chip member 25A in the Z direction.

The pad 20A is coupled to the lead portion 701 of the lead frame 70 by a bonding wire 80A. For example, the pad 20A is coupled to a portion of the lead portion 701 which is on one end side in the X direction.

The pad 21A is coupled to the portion 720 of the electrode 72 by a connection component 5 (hereinafter referred to as a connector). Thus, the pad 21A is electrically coupled to the semiconductor package 1 via the connector 5 and the electrode 72.

The pad 23A is coupled to the die pad 71A via a conductive member 69A, such as solder or a conductive paste. Thus, the pad 23A is coupled to the external connection terminal 75A via the die pad 71A.

The semiconductor chip 2B has a chip member 25B including an element portion 200B (and an interconnect layer). The semiconductor chip 2B has a plurality of pads (also referred to as connection nodes, connection terminals or electrodes) 20B, 21B, 23B inside the chip member 25B. The pads 20B, 21B, 23B are coupled to the element portion 200B in the chip member 25B. An element is formed on the semiconductor substrate in the element portion 200B.

The pads 20B, 21B are provided on the upper surface side of the chip member 25B. The pad 23B is provided on the lower surface side of the chip member 25B. The lower surface of the chip member 25B is the surface of the die pad 71B side. The upper surface of the chip member 25B is opposed to the lower surface of the chip member 25B in the Z direction.

Like the pad 20A, the pad 20B is coupled to the lead portion 701 of the lead frame 70 by a bonding wire 80B. For example, the pad 20B is coupled to a portion of the lead portion 701 which is on the other end side in the X direction.

Like the pad 21A, the pad 21B is coupled to the portion 720 of the electrode 72 by a connector 5. Thus, the pad 21B is electrically coupled to the semiconductor package 1 via the connector 5 and the electrode 72.

The pad 23B is coupled to a die pad 71B via a conductive member 69B. Thus, the pad 23B is coupled to an external connection terminal 75B via the die pad 71B.

For example, the semiconductor device 100 of the present embodiment is a photo relay.

In this case, the semiconductor package 1 is a photocoupler (optical coupling device). The photocoupler includes an optical coupling type insulating circuit.

Each semiconductor chip 2 is a semiconductor element. An example of the semiconductor chip 2 is a field effect transistor. A more specific example of the semiconductor chip 2 is a MOS transistor (e.g., a power MOS transistor).

The semiconductor package 1 and the two semiconductor chips 2 are electrically coupled to each other via various connection members 5, 70, 72.

As shown in FIG. 6, the photocoupler 1 includes a light emitting element 10 and a light receiving element 11 as components of the optical coupling type insulating circuit.

The light emitting element 10 is, for example, an LED (Light Emitting Diode).

One node (e.g., the cathode) of the light emitting element 10 is coupled to the connection terminal 13C. The other node (e.g., the anode) of the light emitting element is coupled to the connection terminal 13D. The connection terminals 13C, 13D are input terminals of the photocoupler 1. An input voltage for controlling the photo relay 100 is applied to the connection terminals 13C, 13D via the electrodes 73, 74 of the package substrate 7 and the external connection terminals 76, 77.

The light receiving element 11 is, for example, a photodiode array. The light receiving element 11 includes, for example, several to several tens of photodiodes 110 coupled in series. The light receiving element 11 may be a phototransistor.

One node (e.g., the cathode) of the light receiving element 11 is coupled to the connection terminal 13B. The other node (e.g., the anode) of the light receiving element 11 is coupled to the connection terminal 13A. The connection terminals 13A, 13B are output terminals of the photocoupler 1.

The MOS transistors 2A, 2B are, for example, enhancement type n-channel MOS transistors. The MOS transistors 2A, 2B are used to control the signal transmission of the photo relay 100. The signal transmitted by the photo relay 100 may be either a DC signal or an AC signal.

The gate (G) of the MOS transistor 2A is coupled to the pad 20A. The source (S) of the MOS transistor 2A is coupled to the pad 21A. The drain (D) of the MOS transistor 2A is coupled to the pad 23A.

The gate (G) of the MOS transistor 2B is coupled to the pad 20B. The source (S) of the MOS transistor 2B is coupled to the pad 21B. The drain (D) of the MOS transistor 2B is coupled to the pad 23B.

The gate of the MOS transistor 2A and the gate of the MOS transistor 2B are commonly coupled to the anode 13A of the light receiving element 11 via a bonding wire 80 and a lead frame 70.

The source of the MOS transistor 2A and the source of the MOS transistor 2B are commonly coupled to the cathode 13B of the light receiving element 11 via the connector 5 and the electrode 72.

The drain of the MOS transistor 2A is coupled to the external connection terminal 75A via the die pad 71A. The drain of the MOS transistor 2B is coupled to the external connection terminal 75B via the die pad 71B.

The external connection terminals 76, 77 serve as input terminals of the photo relay, which is the semiconductor device 100 of the present embodiment. The external connection terminals 75A, 75B serve as output terminals of the photo relay, which is the semiconductor device 100 of the present embodiment.

In the photocoupler 1, the light emitting element 10 outputs light according to the voltage applied to the external connection terminals 76, 77. In this manner, the light emitting element 10 converts an electric signal into an optical signal.

The light receiving element 11 receives an optical signal from the light emitting element 10. The light receiving element 11 generates a voltage of 7 to 10-odd V, depending on the received optical signal. In this manner, the light receiving element 11 converts the optical signal into an electric signal. The light receiving element 11 supplies the generated voltage to the MOS transistor 2 via the lead frame 70 and the bonding wire 80, as the gate voltage of the MOS transistor 2.

Each of the MOS transistors 2A, 2B is driven according to the voltage generated by the light receiving element 11. The MOS transistors 2A, 2B output currents according to the voltages applied to their gates. Therefore, the photo relay 100 transmits a signal when the MOS transistors 2A, 2B are in the ON state.

In the photocoupler 1, when the light emitting element 10 is turned off, the voltage output from the light receiving element 11 is stopped. Therefore, the MOS transistors 2A, 2B are turned off.

As a result, the output terminals 75A, 75B of the photo relay 100 are set in an electrically non-conducting state. Therefore, the photo relay 100 does not transmit a signal when the MOS transistors 2A, 2B are in the OFF state.

The photo relay, which is the semiconductor device 100 of the present embodiment, operates in the above-mentioned manner.

Turning back to FIGS. 2 to 5, a description will be given of the structure of the semiconductor device 100.

In the present embodiment, the connector 5 permits the pads 21A, 21B of the two semiconductor chips 2A, 2B (e.g., the sources of the MOS transistors 2A, 2B) to be coupled to the electrodes 72 on the package substrate 7.

The connector 5 is a plate-shaped conductor. The connector 5 includes, for example, copper.

The connector 5 has a concave cross-sectional shape as viewed in the Y direction. The connector 5 includes first, second, third, fourth and fifth plate portions 50A, 50B, 51, 52A, 52B. The first to fifth plate portions 50A, 50B, 51, 52A, 52B are constituted by one continuous conductive layer (e.g., a copper plate).

The first, second and third plate portions 50A, 50B, 51 spread in a direction parallel to the surface of the package substrate 7. The position of the third plate portion 51 in the Z direction is lower than the positions of the first and second plate portions 50A, 50B in the Z direction (on the side of the package substrate 7 ). The first and second plate portions 50A, 50B are adjacent to each other in a direction parallel to the surface of the package substrate 7 (e.g., in the X direction). The position of the third plate portion 51 in the X direction is located at the center of the connector 5.

The fourth and fifth plate portions 52A, 52B extend in a direction intersecting the surface of the package substrate 7 (e.g., in the direction perpendicular to the surface). For example, the fourth and fifth plate portions 52A, 52B are inclined at a certain angle with reference to the Z direction. The fourth and fifth plate portions 52A, 52B are adjacent to each other in a direction parallel to the surface of the package substrate 7 (e.g., in the X direction).

The fourth plate portion 52A is provided between the first plate portion 50A and the third plate portion 51. The fifth plate portion 52B is provided between the second plate portion 50B and the third plate portion 51.

One end of the first plate portion 50A in the X direction is coupled to the pad 21A of the semiconductor chip 2A via a conductive member 67A, such as solder or a conductive paste. The first plate portion 50A partially (or wholly) overlaps the pad 21A in the Z direction. The upper surface of the pad 21A is covered with the first plate portion 50A.

The other end of the first plate portion 50A as viewed in the X direction is coupled to one end of the fourth plate portion 52A in the Z direction. The other end of the fourth plate portion 52A in the Z direction is coupled to one end of the third plate portion 51 in the X direction. One end of the third plate portion 51 in the X direction is an end portion on the side of the semiconductor chip 2A and an end portion on the side of the die pad 71A.

One end of the second plate portion 50B in the X direction is coupled to the pad 21B of the semiconductor chip 2B via a conductive member 67B. The second plate portion 50B partially (or wholly) overlaps the pad 21B in the Z direction. The upper surface of the pad 21B is covered with the second plate portion 50B.

The other end of the second plate portion 50B in the X direction is coupled to one end of the fifth plate portion 52B in the Z direction. The other end of the fifth plate portion 52B in the Z direction is coupled to one end of the third plate portion 51 in the X direction. The other end of the third plate portion 51 in the X direction is an end portion on the side of the semiconductor chip 2B and an end portion on the side of the die pad 71B.

The third plate portion 51 is coupled to the electrode 72 via a conductive member 68. The third plate portion overlaps the portion 720 of the electrode 72 in the Z direction.

The volume of the plate-shaped connector 5 and the cross-sectional area of the connector in the width direction (Y direction) thereof are larger than the volume and cross-sectional area of the bonding wire.

Therefore, in the semiconductor device 100 of the present embodiment, the connector 5 permits a current having a relatively large current value to flow between the semiconductor package 1 and the semiconductor chip 2.

The semiconductor device 100 of the present embodiment is not limited to the photo relay.

The semiconductor package 1 is not limited to the photocoupler. For example, the semiconductor package 1 may be a discrete device such as a transistor, or may be a semiconductor circuit (e.g., an integrated circuit).

The semiconductor element of the semiconductor chip 2 is not limited to the field effect transistor. For example, the semiconductor chip 2 may include a bipolar transistor or an IGBT (Insulated Gate Bipolar Transistor). The semiconductor chip 2 may be a semiconductor circuit.

### (Digest)

In the semiconductor device 100 of the present embodiment, the semiconductor package 1 and the plurality of semiconductor chips 2 are provided on the package substrate 7.

On the package substrate 7, the semiconductor package 1 and the plurality of semiconductor chips 2 are covered with the package member (resin) 60.

As described above, in the present embodiment, the semiconductor package 1 including the optical device is doubly covered not only with the package member 19 but also with another package member 60.

On the other hand, the semiconductor chip 2 is a bare chip and is covered only with the package member 60 on the package substrate 7.

Therefore, in the present embodiment, a sealed device 1 and an unsealed device 2 are provided on the same package substrate 7.

The semiconductor device 100 of the present embodiment is therefore advantageous in that where the devices 1, 2 on the package substrate 7 are sealed, the restrictions on the material of the package member 60 that seals the devices 1, 2 can be relieved. Thus, the semiconductor device 100 of the present embodiment can realize a double mold structure with relative ease.

In the present embodiment, the use of the bare chip (semiconductor chip 2) in the non-packaged state can suppress the decrease in the space utilization rate in the semiconductor device 100. As a result, the semiconductor device 100 of the present embodiment has a high degree of freedom in terms of the package structure. Therefore, the semiconductor device 100 of the present embodiment can contribute to the miniaturization of semiconductor devices.

Where a semiconductor element constituting the semiconductor device 100 is mounted on the package substrate 7 of a certain area in the state of a semiconductor chip as in the present embodiment, the size of the semiconductor element can be increased as compared with the case where a semiconductor element is mounted on a package substrate 7 of the same area in the state of the package. Thus, the semiconductor device 100 of the present embodiment can reduce the on-resistance.

In the present embodiment, the external connection terminals 75, 76, 77 of the package substrate 7 are provided on the back surface side of the package substrate 7. Thus, the semiconductor device 100 of the present embodiment can reduce the installation area of the semiconductor device 100 on the module board 900.

In the present embodiment, the package substrate 7 includes a lead frame 70. The lead frame 70 has a predetermined shape (interconnect pattern) as a conductive portion (interconnect) of the package substrate 7, and is provided inside the package substrate 7.

Thus, the semiconductor device 100 of the present embodiment is advantageous in that the conductive portion of the package substrate 7 and the devices 1, 2 provided on the package substrate 7 can be coupled to each other in a simplified manner.

In the present embodiment, the two semiconductor chips 2A and 2B are arranged on the package substrate 7 in a symmetrical layout with respect to the semiconductor package 1. Thus, the semiconductor device 100 of the present embodiment is advantageous in that a signal voltage from the semiconductor package 1 can be applied to the two semiconductor chips 2A, 2B in a substantially uniform manner.

As a result, the semiconductor device 100 of the present embodiment enables a stable operation of the semiconductor device 100.

The semiconductor device 100 of the present embodiment can contribute to the miniaturization of the semiconductor device 100 (e.g., reduction of the area) because of the symmetrical layout in which the two semiconductor chips 2A and 2B are provided on the package substrate 7.

In the present embodiment, the plate-shaped connection component (connector) 5 electrically couples a plurality of semiconductor chips 2 to the electrodes 72 of the package substrate 7. Where the volume and cross-sectional area of the connection component 5 increase, the current that flows between the semiconductor chip 2 and the semiconductor package 1 via the connection component 5 (and the electrode 72) increases.

As a result, the semiconductor device 100 of the present embodiment can reduce the on-resistances of the semiconductor chip 2 and the semiconductor device 100. The semiconductor device 100 of the present embodiment can increase the current output from the semiconductor device 100.

The surface area of the connection component 5 through which a large current flow is larger than the surface area of the bonding wire. As a result, in the semiconductor device 100 of the present embodiment, the heat dissipation characteristics of the semiconductor chip 2 and the semiconductor device 100 are improved.

In the present embodiment, the semiconductor chip 2 and the package substrate 7 are coupled to each other by the connection component 5, so that the process of mounting components on the package substrate 7 can be simplified.

According to the present embodiment, the use of the connection component 5 (and the lead frame 70) improves the acceptability and tolerance of misalignment when the semiconductor package 1 and the semiconductor chip 2 are provided on the package substrate 7.

The semiconductor device 100 of the present embodiment is advantageous in that the semiconductor package 1 and the semiconductor chip 2 can be mounted on the package substrate 7 with an improved degree of freedom (e.g., the mounting order can be adjusted) in the process of assembling the semiconductor device 100.

Where the connection component 5 is formed of a plate-shaped conductor and has a concave cross-sectional structure as in the present embodiment, the manufacturing cost of the semiconductor device 100 can be reduced.

As described above, the characteristics of the semiconductor device 100 of the present embodiment are improved.

### Second Embodiment

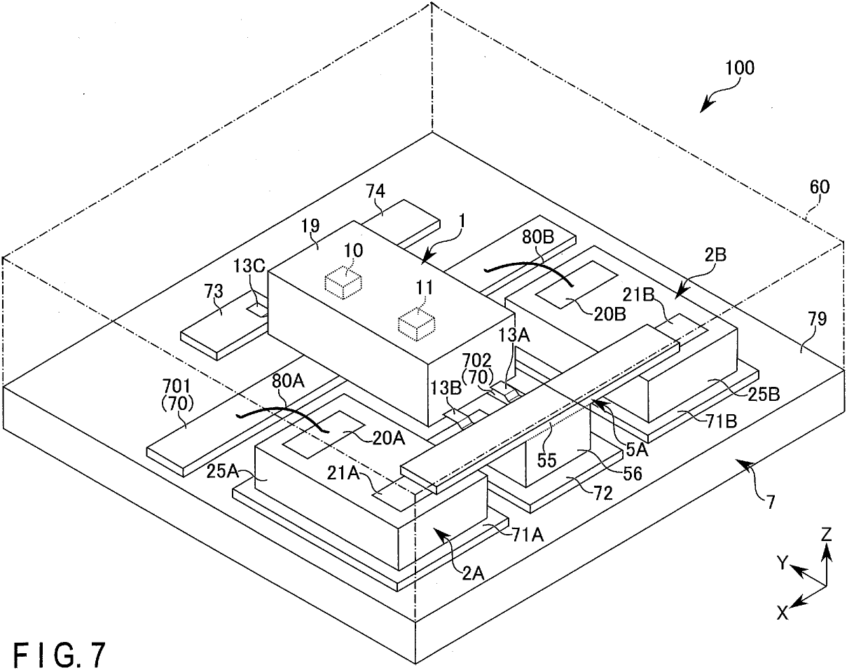

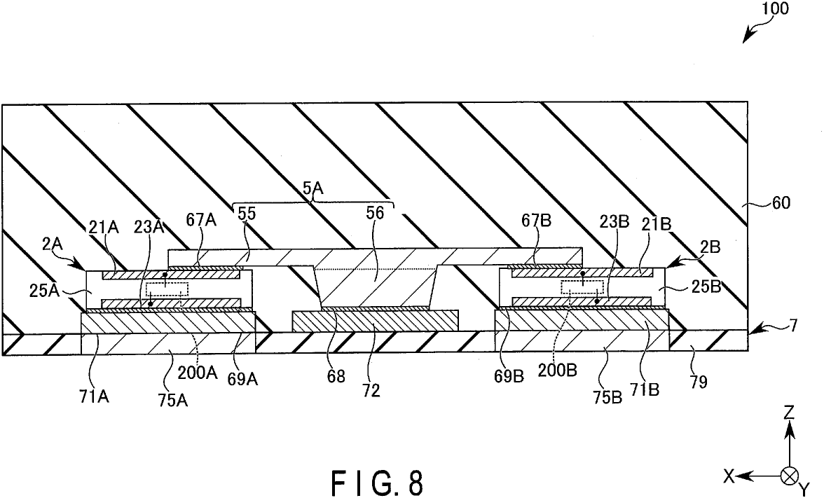

A semiconductor device of the second embodiment will be described with reference to FIGS. 7 and 8.

FIG. 7 is a schematic bird’s-eye view for illustrating the structure of the semiconductor device 100 of the present embodiment. FIG. 8 is a cross-sectional view schematically showing a cross-sectional structure of the semiconductor device 100 of the present embodiment.

As shown in FIGS. 7 and 8, the semiconductor device 100 of the present embodiment differs from the semiconductor device 100 of the first embodiment in terms of the structure of the connector 5 (connection component) 5A.

The connector 5A includes a first portion 55 and a second portion 56. The first portion 55 is one conductor continuous with the second portion 56. The connector 5A includes copper.

The first portion 55 extends along the X-Y plane. The first portion 55 spans two semiconductor chips 2A, 2B. The first portion 55 is coupled to pads 21A, 21B of the semiconductor chips 2A, 2B by conductive members 67A, 67B such as solder or a conductive paste.

The second portion 56 is provided between the first portion 55 and an electrode 72. The second portion 56 is coupled to the electrode 72 by a conductive member 68.

The connector 5A has a T-shaped cross-sectional shape in a cross section as viewed in the Y direction.

In the present embodiment, the connector 5A can have a larger volume.

Owing to the increase in the volume of the connector 5A, the heat dissipation characteristics of the connector 5A are improved.

As the volume (cross-section) of the connector 5A increases, the current flowing between the semiconductor chip 2 and the electrode 72 also increases.

As a result, the semiconductor device 100 of the present embodiment can reduce the on-resistance.

Therefore, the characteristics of the semiconductor device 100 of the present embodiment are improved.

### Modification

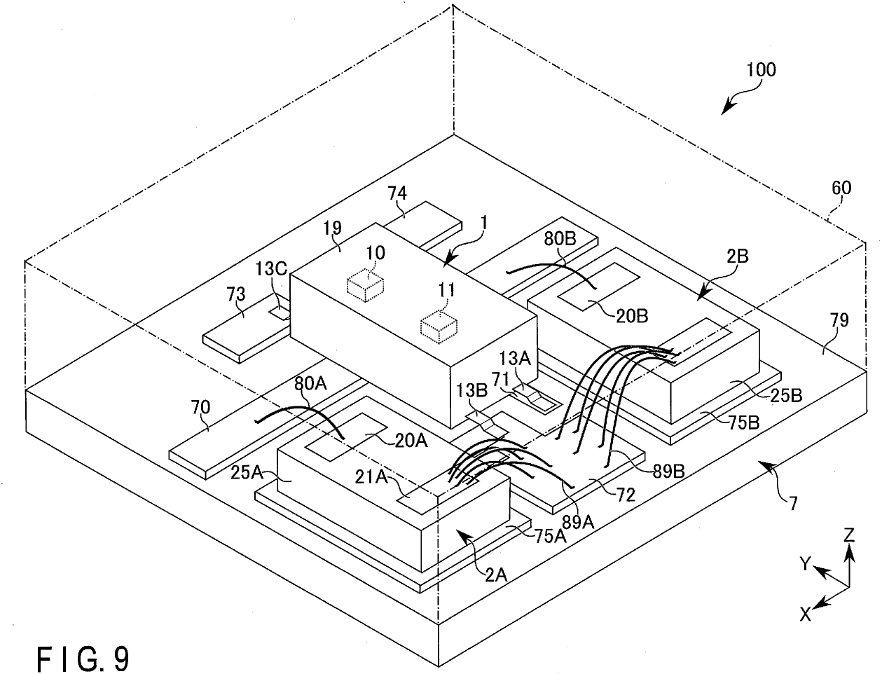

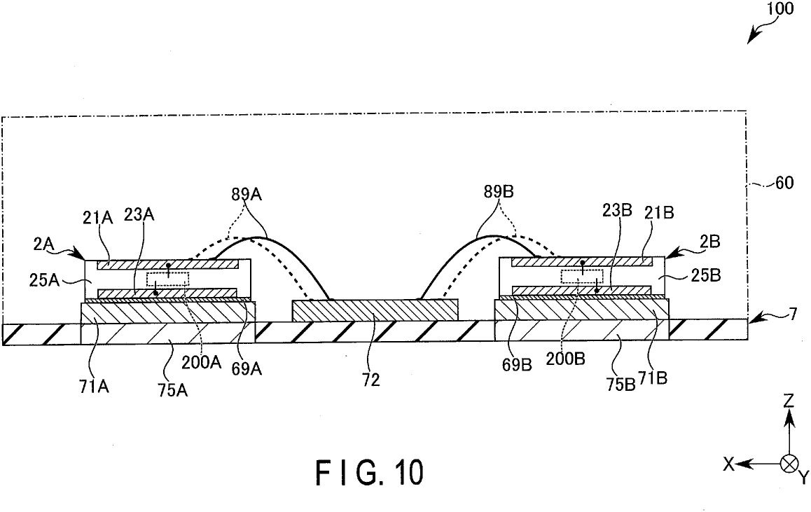

A modification of the semiconductor device of an embodiment will be described with reference to FIGS. 9 and 10.

FIG. 9 is a schematic bird’s-eye view for illustrating a modification example of the semiconductor device 100 of the embodiment. FIG. 10 is a cross-sectional view for illustrating the modification example of the semiconductor device 100 of the present embodiment.

As shown in FIGS. 9 and 10, in the semiconductor device 100 of the present modification, semiconductor chips 2A, 2B are coupled to an electrode 72 of a package substrate 7 by bonding wires 89 (89A, 89B).

A pad 21A of the semiconductor chip 2A is coupled to the electrode 72 via a plurality of bonding wires 89A. The plurality of bonding wires 89A are connected in parallel between the pad 21A and the electrode 72.

A pad 21B of the semiconductor chip 2B is coupled to the electrode 72 via a plurality of bonding wires 89B. The plurality of bonding wires 89B are connected in parallel between the pad 21B and the electrode 72.

The plurality of bonding wires 89 are bonded to the pads 21 and the electrode 72 in the same wire bonding step in which pads 20 and a lead frame 70 are coupled to each other.

The pads 20 of the semiconductor chips 2 may be coupled to the lead frame 70 by using a plate-shaped connection component (connector) instead of the bonding wires 80.

### Others

In connection with the embodiments, an example in which the semiconductor device 100 includes an optical coupling device and a plurality of semiconductor elements is shown. As long as the semiconductor device 100 of the embodiment has a structure including the semiconductor package 1 and the plurality of semiconductor chips 2, the type of device of the semiconductor package 1 and the type of devices of the semiconductor chips 2 are not limited to particular ones.

The number of semiconductor packages 1 included in the semiconductor device 100 of the embodiment may be two or more. Further, the number of semiconductor chips 2 included in the semiconductor device 100 of the embodiment may be three or more.

In the semiconductor device 100 of the embodiment, the semiconductor package 1 and the semiconductor chips 2 are provided on the front surface side of the package substrate 7. However, a semiconductor package, semiconductor chips and various other conductive portions may be provided on both the front surface and the back surface of the package substrate 7.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a package substrate including a package member and a first conductive portion;
a semiconductor package provided on a first surface of the package substrate inside the package member and coupled to the first conductive portion;
a first semiconductor chip provided on the first surface of the package substrate inside the package member and including a first terminal;
a second semiconductor chip provided on the first surface of the package substrate inside the package member and including a second terminal; and
a connection component that couples the first and second terminals to the first conductive portion inside the package member.

2. The semiconductor device according to claim 1, wherein the connection component includes:
a first portion provided on the first terminal;
a second portion provided on the second terminal;
a third portion provided on the first conductive portion;
a fourth portion provided between one end of the first portion and one end of the third portion; and
a fifth portion provided between one end of the second portion and another end of the third portion.

3. The semiconductor device according to claim 1, wherein the connection portion includes:
a sixth portion extending in a first direction parallel to the first surface and spanning the first terminal and the second terminal; and
a seventh portion provided between the first conductive portion and the sixth portion.

4. The semiconductor device according to claim 3, wherein the connection component has a T-shaped cross section, as viewed in a second direction that is parallel to the first surface and that intersects the first direction.

5. The semiconductor device according to claim 1, wherein
the first semiconductor chip is arranged side by side with the second semiconductor chip in a first direction parallel to the first surface, and
the first conductive portion is located between the first semiconductor chip and the second semiconductor chip.

6. The semiconductor device according to claim 5, wherein
the package substrate further includes:
a second conductive portion including a first lead portion and a second lead portion continuous with the first lead portion,
the first lead portion passes through a region which is below the semiconductor package in a second direction perpendicular to the first surface, and extends from a first end side of the package substrate toward a second end side of the package substrate in the first direction, and
the second lead portion passes through a region which is below the semiconductor package in the second direction and extends from the first lead portion toward the first conductive portion in a third direction parallel to the first surface and intersecting the first direction.

7. The semiconductor device according to claim 6, wherein
the first semiconductor chip includes a third terminal,
the second semiconductor chip includes a fourth terminal,
the third terminal is coupled to the first lead portion via a first wire, and
the fourth terminal is coupled to the first lead portion via a second wire.

8. The semiconductor device according to claim 6, wherein
the second conductive portion has a T-shaped planar shape as viewed in a direction perpendicular to the first surface.

9. The semiconductor device according to claim 1, wherein the package substrate further includes:
a first die pad on which the first semiconductor chip is arranged;
a second die pad on which the second semiconductor chip is arranged;
a third conductive portion coupled to a fifth terminal of the semiconductor package; and
a fourth conductive portion coupled to a sixth terminal of the semiconductor package.

10. The semiconductor device according to claim 9, wherein the package substrate further includes:
a first connection terminal provided on a second surface side of the package substrate which is opposite to the first surface in a second direction perpendicular to the first surface, overlapping the first die pad in the second direction, and coupled to the first die pad;
a second connection terminal provided on the second surface side, overlapping the second die pad in the second direction, and coupled to the second die pad;
a third connection terminal provided on the second surface side, overlapping the third conductive portion in the second direction, and coupled to the third conductive portion; and
a fourth connection terminal provided on the second surface side, overlapping the fourth conductive portion in the second direction, and coupled to the fourth conductive portion.

11. The semiconductor device according to claim 10, wherein
the first to fourth connection terminals are exposed from the second surface.

12. The semiconductor device according to claim 1, wherein
the first semiconductor chip is arranged side by side with the second semiconductor chip in a first direction parallel to the first surface,
the semiconductor package is arranged in a region between the first semiconductor chip and the second semiconductor chip, and
the first and second semiconductor chips are arranged on the package substrate symmetrically, with a line passing through a center of the semiconductor package as an axis of symmetry.

13. The semiconductor device according to claim 1, wherein the semiconductor package includes an optical coupling device.

14. The semiconductor device according to claim 1, wherein each of the first and second semiconductor chips includes a transistor.

15. The semiconductor device according to claim 1, wherein the semiconductor package includes:
a package layer covered with the package member; and
a circuit portion covered with the package layer.

16. The semiconductor device according to claim 1, wherein the connection component includes copper.

17. The semiconductor device according to claim 1, wherein the connection portion includes a wire.

18. The semiconductor device according to claim 1, wherein the first and second semiconductor chips are sealed by the package member.

19. The semiconductor device according to claim 1, wherein the package substrate includes a ceramic material.
